(19) United States
(12) Patent Application Publication
(10) Pub. No.: US 2025/0314731 A1
(43) Pub. Date: Oct. 9, 2025

(54) EVALUATION AND CORRECTION OF CURRENT SENSING DEVICES

(71) Applicant: GM Global Technology Operations LLC, Detroit, MI (US)

(72) Inventor: Vinod Chowdary Peddi, Shelby Township, MI (US)

(21) Appl. No.: 18/626,809

(22) Filed: Apr. 4, 2024

(51) Int. Cl. G01R 35/00; G01R 19/25

(52) U.S. Cl. CPC G01R 35/00; G01R 19/2506

(57) ABSTRACT

A system for evaluating current sensor measurements includes a current sensor configured to measure three-phase alternating current (AC) signals applied to a three-phase electrical device, the measured AC signals including a first measurement of a first phase current, a second measurement of a second phase current and a third measurement of a third phase current, and an error detection module configured to receive the measured AC signals. The error detection module is configured to apply a transform to the measured AC signals to generate a plurality of reference currents, each reference current of the plurality of reference currents represented as a current vector rotating in a two-dimensional reference frame, calculate a current angle between the plurality of reference currents, correlate the current angle to a second order harmonic function, and determine a gain error associated with the measured AC signals based on the correlating.

### INTRODUCTION

The subject disclosure relates to current sensing, and more specifically, to detection and correction of errors in three-phase current sensors.

Vehicles, including gasoline and diesel power vehicles, as well as electric and hybrid electric vehicles, feature battery storage for purposes such as powering electric motors, electronics and other vehicle subsystems. Power electronics (e.g., inverters and direct current (DC)-DC converters) in a vehicle are responsible for functions such as controlling power and electrical energy to components such as electric motors and other electrical components. Various sensors, including current sensors, are important for ensuring proper motor control and for proper function of power electronic devices. For example, current sensors are important for effective control of phase currents when driving electric motors.

### SUMMARY

In one exemplary embodiment, a system for evaluating current sensor measurements includes a current sensor configured to measure three-phase alternating current (AC) signals applied to a three-phase electrical device, the measured AC signals including a first measurement of a first phase current, a second measurement of a second phase current and a third measurement of a third phase current, and an error detection module configured to receive the measured AC signals. The error detection module is configured to applying a transform to the measured AC signals to generate a plurality of reference currents, each reference current of the plurality of reference currents represented as a current vector rotating in a two-dimensional reference frame, calculate a current angle between the plurality of reference currents, correlate the current angle to a second order harmonic function, and determine a gain error associated with the measured AC signals based on the correlating.

In addition to one or more of the features described herein, the three-phase electrical device includes an electric motor configured to drive a vehicle.

In addition to one or more of the features described herein, the second order harmonic function is a second order rotating complex vector having a real part and an imaginary part.

In addition to one or more of the features described herein, determining the gain error includes estimating a first gain error associated with the first measurement based on the real part, and determining a combined gain error associated with the second measurement and the third measurement based on the imaginary part.

In addition to one or more of the features described herein, the error detection module is configured to apply a gain correction to each of the first measurement, the second measurement and the third measurement.

In addition to one or more of the features described herein, applying the gain correction includes distributing the combined gain error, correcting the second measurement based on a first portion of the combined gain error and correcting the third measurement based on a second portion of the combined gain error.

In addition to one or more of the features described herein, the first portion and the second portion are selected to reduce or minimize current ripple and torque errors.

In addition to one or more of the features described herein, the error detection module is configured to correct an offset error of the plurality of reference currents, based on applying a low pass filter to the plurality of reference currents.

In another exemplary embodiment, a method of evaluating current sensor measurements includes measuring, by a current sensor, three-phase alternating current (AC) signals applied to a three-phase electrical device, the measured AC signals including a first measurement of a first phase current, a second measurement of a second phase current and a third measurement of a third phase current, and applying a transform to the measured AC signals to generate a plurality of reference currents, each reference current of the plurality of reference currents represented as a current vector rotating in a two-dimensional reference frame. The method also includes calculating a current angle between the plurality of reference currents, correlating the current angle to a second order harmonic function, and determining a gain error associated with the measured AC signals based on the correlating.

In addition to one or more of the features described herein, the second order harmonic function is a second order rotating complex vector having a real part and an imaginary part.

In addition to one or more of the features described herein, determining the gain error includes estimating a first gain error associated with the first measurement based on the real part, and determining a combined gain error associated with the second measurement and the third measurement based on the imaginary part.

In addition to one or more of the features described herein, the method includes applying a gain correction to each of the first measurement, the second measurement and the third measurement.

In addition to one or more of the features described herein, applying the gain correction includes distributing the combined gain error, correcting the second measurement based on a first portion of the combined gain error and correcting the third measurement based on a second portion of the combined gain error.

In addition to one or more of the features described herein, the first portion and the second portion are selected to reduce or minimize current ripple and torque errors.

In addition to one or more of the features described herein, the method includes correcting an offset error of the reference currents, based on applying a low pass filter to the reference currents.

In yet another exemplary embodiment, a vehicle system includes a memory having computer readable instructions and a processing device for executing the computer readable instructions, the computer readable instructions controlling the processing device to perform a method. The method includes receiving, from a current sensor, measurements of three-phase alternating current (AC) signals applied to a three-phase electrical device, the measurements including a first measurement of a first phase current, a second measurement of a second phase current and a third measurement of a third phase current. The method also includes applying a transform to the measurements to generate a plurality of reference currents, each reference current if the plurality of reference currents represented as a current vector rotating in a two-dimensional reference frame, calculating a current angle between the plurality of reference currents, correlating the current angle to a second order harmonic function, and determining a gain error associated with the measurements based on the correlating.

In addition to one or more of the features described herein, the second order harmonic function is a second order rotating complex vector having a real part and an imaginary part.

In addition to one or more of the features described herein, determining the gain error includes estimating a first gain error associated with the first measurement based on the real part, and determining a combined gain error associated with the second measurement and the third measurement based on the imaginary part.

In addition to one or more of the features described herein, the method includes applying a gain correction to each of the first measurement, the second measurement and the third measurement, wherein applying the gain correction includes distributing the combined gain error, correcting the second measurement based on a first portion of the combined gain error and correcting the third measurement based on a second portion of the combined gain error.

In addition to one or more of the features described herein, the method includes correcting an offset error of the plurality of reference currents, based on applying a low pass filter to the plurality of reference currents.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a schematic, top view of a motor vehicle, in accordance with an exemplary embodiment;

FIG. 2 schematically depicts components of an inverter module including a current measurement and/or control system, in accordance with an exemplary embodiment;

FIG. 3 depicts a control system for controlling three-phase current applied to an electrical device or system, which includes components for error detection and/or compensation, in accordance with an exemplary embodiment;

FIG. 4 depicts aspects of sensor error detection and compensation, in accordance with an exemplary embodiment;

FIG. 5 is a flow diagram depicting a method of detecting and learning current sensor errors and/or correcting current sensor measurements, in accordance with an exemplary embodiment;

FIG. 6 is a normalized vector plot of three-phase currents represented in an αβ reference frame;

FIG. 7 is a graph depicting sensor angles and showing effects of sensor errors; and

FIG. 8 depicts a computer system in accordance with an exemplary embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

In accordance with an exemplary embodiment, methods, devices and systems are provided for current sensing, error detection and/or current sensor measurement correction. An embodiment of a current sensing system includes one or more current sensors configured to detect current supplied to a vehicle motor or other three-phase electrical system, and processing device configured to detect and learn sensor errors. The current sensing system may be incorporated as part of a control system (e.g. motor controller) for controlling a power conversion device such as an inverter of a vehicle that is connected to an electric motor.

An embodiment of a method includes acquiring three-phase current measurements (also referred to as “measured currents” or “current measurements”), and applying a transformation to generate reference currents. In an embodiment, the reference currents are transformed to rotating phase vectors in a two-dimensional reference frame (e.g., a αβγ transformation). Offset errors may be corrected using a low pass filter.

Gain errors associated with each measured phase current are learned by correlating a current angle (angle between the reference currents, such as α and β currents) to a second order harmonic function. For example, the reference currents are correlated with a second order complex vector, and real and imaginary components are separately integrated until zero to derive the gain errors.

Embodiments described herein present numerous advantages and technical effects. The embodiments provide for effective correction of errors in current sensors, which can arise due to various conditions. For example, automotive current sensors suffer from offset and gain errors due to temperature variation and aging, leading to torque ripple and torque offset issues. The embodiments provide for effective and efficient error correction, as the methods may be performed using existing components and only require current measurements and signal processing. In addition, error learning can be adapted to a wide variety of operating conditions (e.g., various vehicle speeds and torque conditions). Furthermore, errors can be learned and compensated for in real time and used in highly dynamic environments such as traction motors.

The embodiments are not limited to use with any specific vehicle or electronic device, and may be applicable to various contexts. For example, embodiments may be used with automobiles, trucks, aircraft, construction equipment, farm equipment, automated factory equipment and/or any other device or system for which additional thermal control may be desired to facilitate a device or system's existing thermal control capabilities or features.

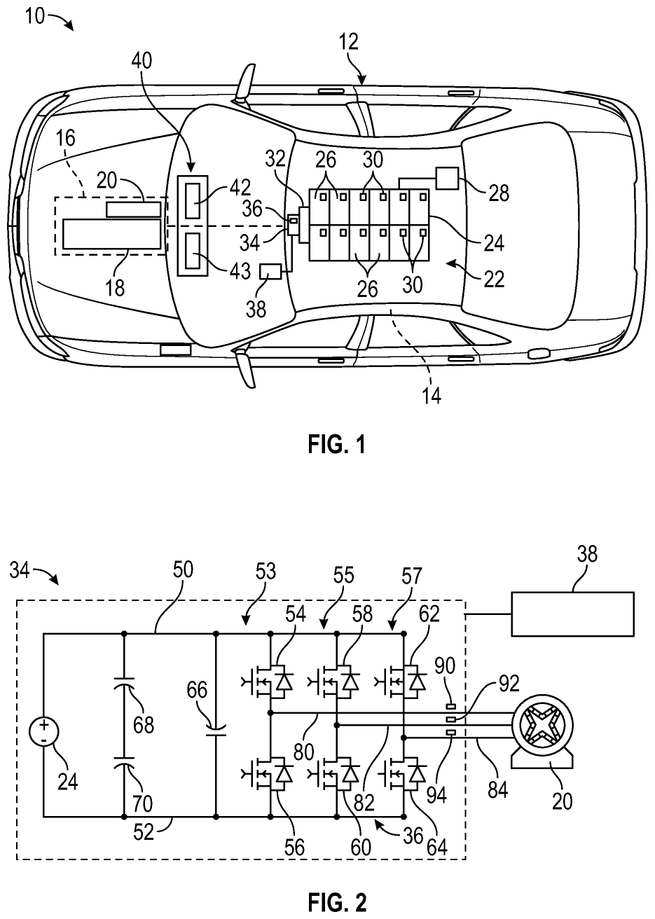

FIG. 1 shows an embodiment of a motor vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, a fuel injection subsystem, an exhaust subsystem and others.

The vehicle 10 may be a combustion engine vehicle, an electrically powered vehicle (EV) or a hybrid vehicle. In an embodiment, the vehicle 10 is a hybrid vehicle that includes a combustion engine assembly 18 and at least one electric motor assembly. In this embodiment, the propulsion system 16 includes an electric motor 20, and may include one or more additional motors positioned at various locations.

The vehicle 10 includes a battery system 22, which may be electrically connected to the motor 20 and/or other components, such as vehicle electronics. The battery system 22 may be configured as a rechargeable energy storage system (RESS).

In an embodiment, the battery system 22 includes a battery assembly such as a high voltage battery pack 24 having a plurality of battery modules 26. Each of the battery modules 26 includes a number of individual cells (not shown). The battery system 22 may also include a monitoring unit 28 configured to receive measurements from sensors 30.

The battery system 22 is electrically connected to a direct current (DC)-DC converter module 32 and an inverter module 34. The inverter module 34 (e.g., a traction power inverter unit or TPIM) converts DC power from the battery system 22 to three-phase alternating current (AC) power to drive the motor 20. In an embodiment, the inverter module 34 includes an inverter 36 connected to the DC-DC-converter module 34 for receiving DC power, and is connected to the motor 20 for providing three-phase AC power thereto.

One or more processing devices are included to control operation of the propulsion system. In an embodiment, the vehicle 10 includes a motor control unit (MCU) 38 configured to control operation of the motor 20 by controlling three-phase current output from the inverter 36. Other control units may be included, such an engine controller (not shown).

The vehicle 10 also includes a computer system 40 that includes one or more processing devices 42 and a user interface 43. The various processing devices and units may communicate with one another via a communication device or system, such as a controller area network (CAN) or transmission control protocol (TCP) bus.

FIG. 2 schematically illustrates components of an embodiment of the propulsion system 16, including the inverter module 34, the motor 20 and the MCU 38. The inverter module 34 includes a three-phase inverter circuit (inverter 36). The inverter module 34 may be incorporated into the vehicle 10, another vehicle or any other system.

The MCU 38 is configured to perform functions including sensor correction as described herein. The MCU 38 may also control functions of the inverter 36 and/or the motor 20. The MCU 38 may be part of an electronic control unit (ECU), a motor controller, a TPIM controller, or may be a separate dedicated controller.

The inverter 36 includes three sets of switches connected in parallel to a positive DC bus 50 and a negative DC bus 52. Each set of switches is in a half-bridge configuration. A first set of switches 54 and 56 is connected to a first motor phase (phase A), a second set of switches 58 and 60 connected to a second motor phase (phase B), and a third set of switches 62 and 64 is connected to a third motor phase (phase C). In an embodiment, the sets of switches are incorporated into one or more switching modules. The inverter module 34 also includes various capacitors for stabilizing operation, such as a bulk DC capacitor 66 and bypass capacitors 68 and 70.

Each set of switches is connected by a conductor to a phase of the motor 20. For example, the first set of switches 54 and 56 is connected by a conductor 80 to a first phase (phase A) of the motor 20. The second set of switches 58 and 60 is connected by a conductor 82 to a second phase (phase B). The third set of switches 62 and 64 is connected by a conductor 84 to a third phase (phase C).

Various sensors (e.g., voltmeters, current sensors, etc.) are disposed relative to components of the inverter module 34. For example, a first current sensor 90 is configured to measure phase A current, a second current sensor 92 is configured to measure phase B current, and a third current sensor 94 is configured to measure phase C current.

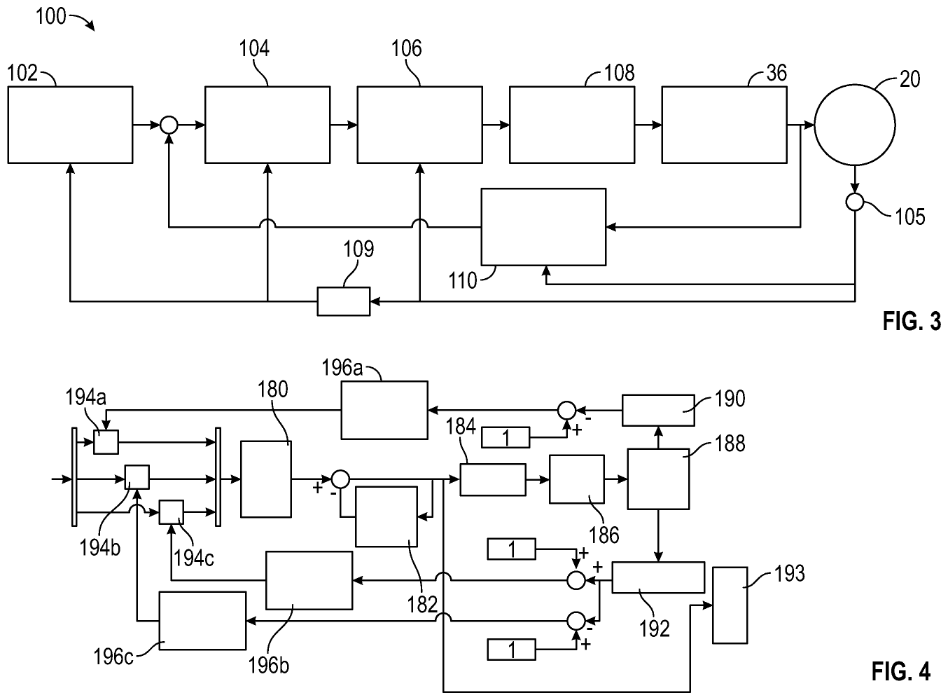

FIG. 3 depicts an embodiment of a control system 100, which may be embodied as the MCU 38, or any other suitable processing device or controller. The control system 100 receives a torque command for applying an amount of torque Tₑ, and also receives a DC voltage V_{de} of a power supply (e.g., vehicle battery system) and a motor speed ωₑ. A torque to current conversion module 102 converts the inputs to in-phase and quadrature (d-q) current command signals I_{dq}. The current command signals I_{dq} are provided to a current regulator 104, which calculates d-q voltage commands V_{dq}.

The d-q voltage commands, and motor position θₑ, (e.g., from a position sensor 105) are input to a converter 106, and the d-q voltage commands are converted to three-phase voltage V_{abc}. The voltage V_{abc} is modulated by a modulator 108 to produce modulated voltage pulses that are applied to the inverter 36. In an embodiment, the voltage V_{abc} is modulated using pulse width modulation (PWM).

Current measurement is critical for accurate control of torque in the vehicle system. Any errors in a current measurement (e.g., due to sensor errors and/or analog-to-digital conversion errors) can lead to undesired torque ripple causing noise, vibration and harshness, and DC torque errors.

To determine current sensor errors and compensate for such errors, the control system includes a sensor error compensation module 110, which is configured to receive measured phase A, B and C currents (I_{abc,measured}) and motor position, learn sensor errors and correct current measurements before providing such measurements to the control system. For example, as shown in FIG. 3, the sensor error compensation module 110 converts the measured phase currents to d-q currents while correcting for sensor errors (e.g., gain and offset errors). The result is corrected d-q currents (I_{dq,corrected}) which are fed to the current regulator 104, along with dynamic motor position and/or motor speed information (represented by block 109.

In an embodiment, the compensation module (or other processing device), is configured to learn and diagnose sensor errors in real time (e.g., during vehicle operation).

FIG. 4 is a block diagram that illustrates aspects of current sensor error detection and error compensation performed by the sensor error compensation module 110. Although aspects of error detection and compensation methods are described in conjunction with the module 110, embodiments are not so limited, as the methods can be performed by any suitable controller, module, processing device or processing system.

In a typical three phase system, measured currents can be modeled as spatially 120 degrees apart sinusoidal components. The errors from the current sensor can be modeled as the following:

$$\begin{matrix}{I}_{a , measured} = {K}_{a} * I * sin θ + {A}_{o} ; \\ {I}_{b , m e a s u r e d} = {K}_{b} * I * sin θ - 2 π / 3 + {B}_{o} ; \\ {I}_{a , measured} = {K}_{c} * I * sin θ + 2 π / 3 + {C}_{o}\end{matrix} \qquad ( 1 )$$

where Kₐ, K_{b} and K_{c} are gain errors. Aₒ, Bₒ and Cₒ are offset errors of three phases. Gain and offset errors are typically caused due to temperature variation, aging of the sensors and ADCs. Errors can also be inherent properties of the sensing technologies. The methods described herein may be used to determine the gain errors and may also be used to determine the offset errors.

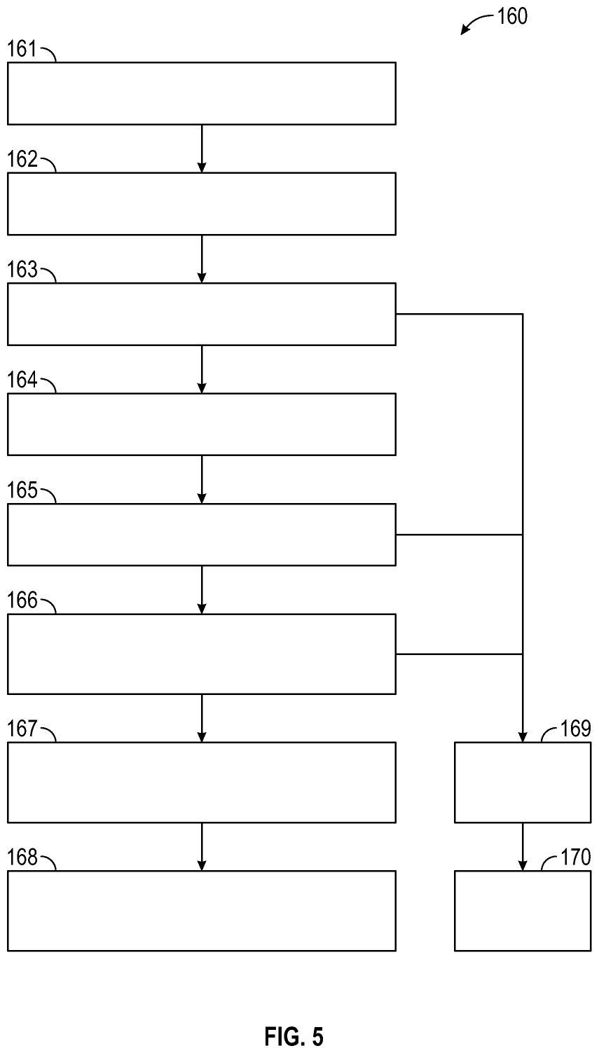

FIG. 5 illustrates embodiments of a method 160 of measuring current, detecting current sensor errors and correcting or compensating for such errors. The method 160 may be performed in conjunction with a vehicle conversion device, such as the inverter module 34. However, the method 160 is not so limited and may be used with any suitable electrical device or system.

Aspects of the method 160 may be performed by a suitable processing device. For example, the method 160 is discussed in conjunction with the error compensation module of FIG. 4.

The method 160 includes a number of steps or stages represented by blocks 161-170. The method 160 is not limited to the number or order of steps therein, as some steps represented by blocks 161-170 may be performed in a different order than that described below, or fewer than all of the steps may be performed.

At block 161, the inverter module 34 is operated and three-phase current is supplied to the motor 20. Current (AC signals) through each of the conductors 80, 82 and 84 (referred to as “phase currents”) is measured, resulting in current measurements for each phase. The current measurements may also be referred to as measured phase currents I_{abc,measured} (e.g., measured phase A current, measured phase B current and measured phase C current).

At block 162, a transform is applied to the measured phase currents to generate reference currents (FIG. 4, block 180). The reference currents are represented as a current vector rotating in a two-dimensional reference frame.

For example, the measured phase currents are processed using an αβγ transformation. The gamma term is set to zero, such that the transformation is scale-invariant.

The αβγ transformation is applied to equations (1), yielding the following measured α current (I_{α,measured}) and measured β current (I_{β,measured}), collectively referred to as I_{αβ,measured}:

$$[ \begin{matrix}{I}_{α , measured} \\ {I}_{β , measured}\end{matrix} ] = \frac{1}{\sqrt{3}} [ \begin{matrix}2 & - 1 & - 1 \\ 0 & \sqrt{3} & - \sqrt{3}\end{matrix} ] [ \begin{matrix}{I}_{a , measured} \\ {I}_{b , measured} \\ {I}_{c , measured}\end{matrix} ] ; \qquad ( 2 )$$

$${I}_{α , measured} = \frac{1}{3} ( 2 {K}_{a} + \frac{{K}_{b}}{2} + \frac{{K}_{c}}{2} ) * I * sin θ + \frac{1}{2 \sqrt{3}} ( {K}_{b} - {K}_{c} ) * cos θ + {I}_{α , Offset} ;$$

$${I}_{β , measured} = ( \frac{{K}_{b}}{2} + \frac{{K}_{c}}{2} ) * I * cos θ + \frac{1}{2 \sqrt{3}} ( {K}_{b} - {K}_{c} ) * sin θ + {I}_{β , Offset}$$

I_{α,Offset} and I_{β,Offset} are offsets that are a function of the offset errors, where:

$$\begin{matrix}{I}_{α , Offset} = 2 {A}_{o} - {B}_{o} - {C}_{o} , and \\ {I}_{β , Offset} = {B}_{o} - {C}_{o} .\end{matrix} \qquad ( 3 )$$

At block 163, the measured αβ currents I_{α,measured} and I_{β,measured} are filtered using a low pass filter 182 (FIG. 4), so that offset errors are removed. The low pass filter parameters (e.g., cutoff frequency) are selected so that the offset errors are isolated. Filtering also allows the system to learn the offset errors.

In an embodiment, offset error learning is triggered based on thresholds related to motor speed, cycles and/or current magnitude. For example, a minimum motor speed and current magnitude is selected, and offset error learning is performed if motor speed, voltage and current magnitude are at or above the minimum values. A low pass filter having a z-transform function (KₒTₛ/(1−z⁽⁻¹⁾) may be used, including a pulse width parameter Tₛ, and a filter parameter Kₒ that is selected to set the filter cutoff frequency. For example, the filter frequency can be set to be low (e.g., 0.1 to 1 Hz) to provide for relatively slow learning.

The learned offset errors may be diagnosed by comparing the offset errors to one or more thresholds associated with various error conditions (block 169) and/or stored for later analysis and/or use in subsequent error detection and compensation methods.

At block 164, gain errors are compensated by correlating an error signature to a second order harmonic function. For example, errors are correlated with a complex vector of current angle to learn the gain errors. Gain error determination may be triggered by sufficiently high voltage and motor speed.

Gain errors due to measuring phase A current are denoted as Kₐ, gain errors due to measuring phase B current are denoted as K_{b}, and gain errors due to measuring phase C current are denoted as K_{c}. The gain errors can be represented in the following equations:

$$\begin{matrix}{I}_{α , measured} = \frac{1}{3} ( 2 {K}_{a} + \frac{{K}_{b}}{2} + \frac{{K}_{c}}{2} ) * I * sin θ + \frac{1}{2 \sqrt{3}} ( {K}_{b} - {K}_{c} ) * cos θ ; \\ {I}_{β , measured} = ( \frac{{K}_{b}}{2} + \frac{{K}_{c}}{2} ) * I * cos θ + \frac{1}{2 \sqrt{3}} ( {K}_{b} - {K}_{c} ) * sin θ\end{matrix} \qquad ( 4 )$$

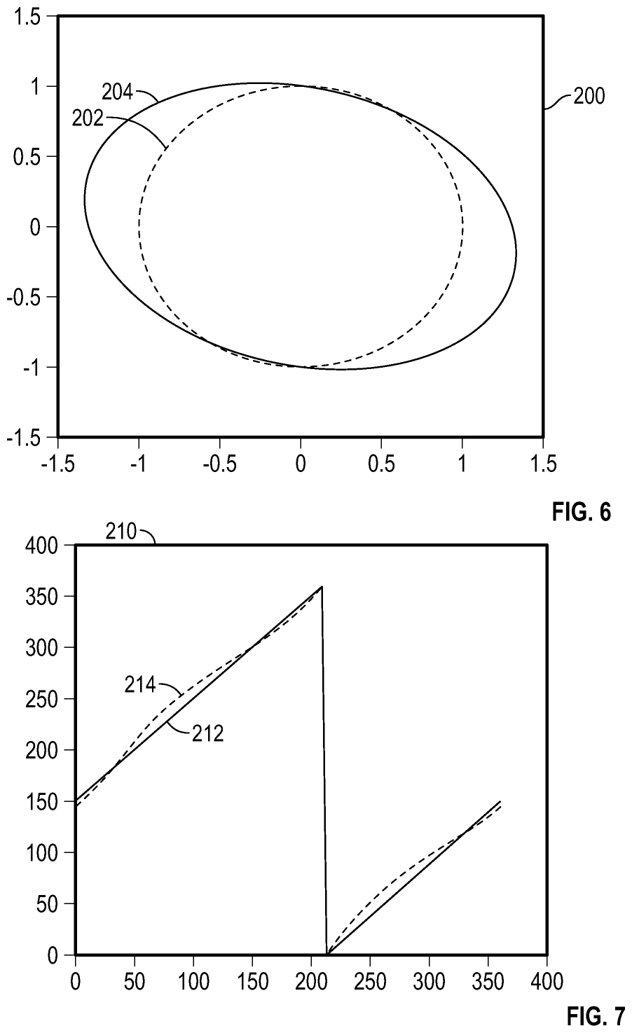

As discussed further herein (See discussion with reference to FIGS. 6 and 7), gain errors can result in second order harmonics. As a result, it can be assumed that that the current angle (angle between α and β currents) would have a second order harmonic. Current angle Φ can be defined as:

$$Φ = a tan 2 ( {I}_{β , measured} {I}_{α , measured} ) \qquad ( 5 )$$

In an embodiment, the error present in the current angle is correlated with a second order rotating complex vector defined as:

$${e}^{j * 2 * Φ} = cos ( 2 * Φ ) + sin ( 2 * Φ ) , \qquad ( 6 )$$

where the cosine term is the real part and is associated with phase A gain errors. The sine term is the imaginary part and is associated with a combination of phase B and phase C errors. The correlation is shown in FIG. 4 as determining current angle at block 184 (atan2 function), performing complex vector correlation at block 186 and integrating using an integrator 188.

At block 165, the phase A gain error is estimated by integrating the complex vector to drive the real part of the complex vector to zero.

At block 166, the complex vector is integrated to drive the imaginary part of the complex vector to zero, to obtain a combined phase B and phase C gain error. The learned values may be limited as a function of operating point based on torque, motor speed, Vdc (DC bus voltage), and rationalized and diagnosed (block 169) and stored in memory (block 170).

In an embodiment, as shown in FIG. 4, the complex vector is integrated by an integrator 188 to drive the second order content in the current angle to zero, and to separate the real part (phase A gain errors, block 190) and the imaginary part (phase B and C gain errors, block 192). For example, integration is performed by correlating current angle (from block 184) to a second harmonic rotating complex vector (block 186) and is integrated by the integrator 188. The real and imaginary parts are taken and the gain errors are extracted.

At block 167, the gain errors are dynamically limited based on operating conditions. Dynamic limiting of each phase gain error and distribution of the errors among three phases ensures that torque ripple and DC torque error occurrences are reduced or eliminated. For example, motor speed and voltage are determined and a limit is applied to each gain error prior to correction.

An example of gain error limiting is shown in FIG. 4 as block 196a for phase A gain error limiting, as block 196b for phase B gain error limiting, and as block 196c for phase C gain error limiting. These limits are dynamic and thus can be changed as operating conditions change.

At block 168, the learned gain errors are used to correct the measured currents. The measured currents are controlled to adapt the current measurements so that the gain errors are minimized. For example, the real part is compared to an ideal case (Kₐ=1) and the difference is provided to correct the phase A measured current (block 194a, FIG. 4), optionally with dynamic limiting.

The combined phase B and phase C gain errors are distributed among the phase B and phase C measured currents. The distribution is selected to reduce or eliminate torque ripple and DC Torque offsets, and results in a first portion of the combined errors being applied to correct phase B current measurements (block 194b, FIG. 4), and a second portion of the combined errors being applied to correct phase C measurements (block 194c).

In an example, the gain error compensation technique is analogous to model reference adaptive control (MRAC) where a plant or system is forced to behave like a reference model. In addition, if a detected gain error is too high, an alert may be generated and/or a mitigating action may be performed (e.g., shutoff or torque reduction).

Extraction of gain errors and correction of current measurements, in an embodiment, is performed iteratively in a closed loop manner, and over time, the gain errors converge to real values. The integrator 188 may thus learn the gain error values in real time. The integrator 188 also ensures any change is also learned within a certain bandwidth. For example, the integrator uses a function (K_{g}Tₛ/(1−z⁽⁻¹⁾) having a K_{g} parameter that is selected to set the bandwidth. Kg can also be modified as a function of operating point (e.g., torque/speed) to different adaptive learning rates.

FIG. 6 illustrates an example of the gain errors, and illustrates the second order harmonic content that is determined by the methods described herein. In this example, the measured alpha currents and beta currents are normalized and plotted as a function of each other in a graph 200.

As can be seen, there is a deviation between an ideal vector plot 202 and a measured vector plot 204. This deviation or “wobble” is indicative of the second order harmonic content due to gain errors.

The second order harmonic content is also present in the current angle. FIG. 7 shows a graph 210 of current angle of ideal current vs current angle with gain errors, which correspond to the second order harmonic content. Curve 212 shows an ideal current angle curve and curve 214 shows a current angle curve corresponding to measured current angle with gain errors.

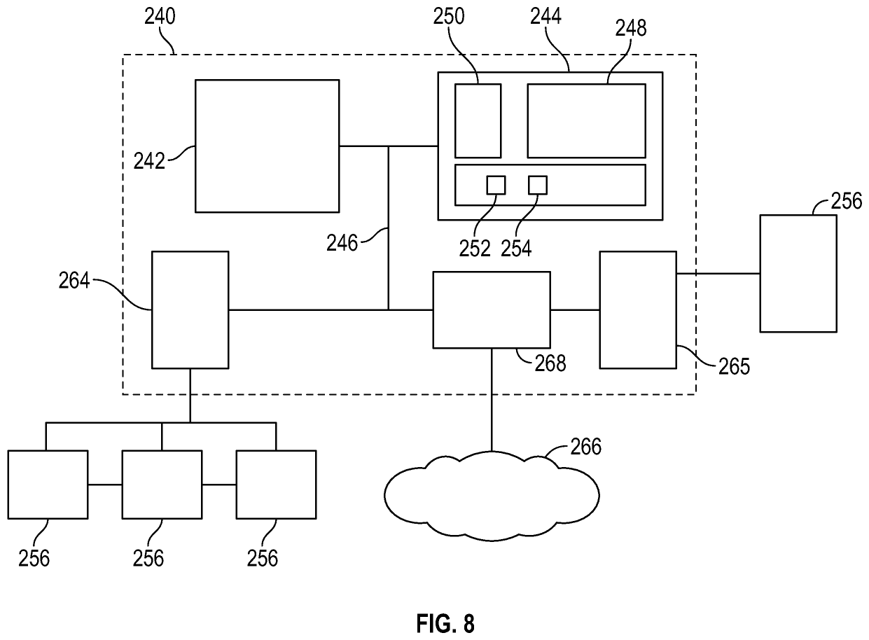

FIG. 8 illustrates aspects of an embodiment of a computer system 240 that can perform various aspects of embodiments described herein. The computer system 240 includes at least one processing device 242, which generally includes one or more processors for performing aspects of image acquisition and analysis methods described herein.

Components of the computer system 240 include the processing device 242 (such as one or more processors or processing units), a memory 244, and a bus 246 that couples various system components including the system memory 244 to the processing device 242. The system memory 244 can be a non-transitory computer-readable medium, and may include a variety of computer system readable media. Such media can be any available media that is accessible by the processing device 242, and includes both volatile and non-volatile media, and removable and non-removable media.

For example, the system memory 244 includes a non-volatile memory 248 such as a hard drive, and may also include a volatile memory 250, such as random access memory (RAM) and/or cache memory. The computer system 240 can further include other removable/non-removable, volatile/non-volatile computer system storage media.

The system memory 244 can include at least one program product having a set (e.g., at least one) of program modules that are configured to carry out functions of the embodiments described herein. For example, the system memory 244 stores various program modules that generally carry out the functions and/or methodologies of embodiments described herein. A module 252 may be included for performing functions related to motor control and/or current regulation, and a module 254 may be included to perform functions related to error detection and correction of current measurements as discussed herein. The system 240 is not so limited, as other modules may be included. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 242 can also communicate with one or more external devices 256 as a keyboard, a pointing device, and/or any devices (e.g., network card, modem, etc.) that enable the processing device 242 to communicate with one or more other computing devices. Communication with various devices can occur via Input/Output (I/O) interfaces 264 and 265.

The processing device 242 may also communicate with one or more networks 266 such as a local area network (LAN), a general wide area network (WAN), a bus network and/or a public network (e.g., the Internet) via a network adapter 268. It should be understood that although not shown, other hardware and/or software components may be used in conjunction with the computer system 40. Examples include, but are not limited to: microcode, device drivers, redundant processing units, external disk drive arrays, RAID systems, and data archival storage systems, etc.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A system for evaluating current sensor measurements, comprising:
a current sensor configured to measure three-phase alternating current (AC) signals applied to a three-phase electrical device, the measured AC signals including a first measurement of a first phase current, a second measurement of a second phase current and a third measurement of a third phase current; and
an error detection module configured to receive the measured AC signals and perform:
applying a transform to the measured AC signals to generate a plurality of reference currents, each reference current of the plurality of reference currents represented as a current vector rotating in a two-dimensional reference frame;
calculating a current angle between the plurality of reference currents;
correlating the current angle to a second order harmonic function; and
determining a gain error associated with the measured AC signals based on the correlating.

2. The system of claim 1, wherein the three-phase electrical device includes an electric motor configured to drive a vehicle.

3. The system of claim 1, wherein the second order harmonic function is a second order rotating complex vector having a real part and an imaginary part.

4. The system of claim 3, wherein determining the gain error includes estimating a first gain error associated with the first measurement based on the real part, and determining a combined gain error associated with the second measurement and the third measurement based on the imaginary part.

5. The system of claim 4, wherein the error detection module is configured to apply a gain correction to each of the first measurement, the second measurement and the third measurement.

6. The system of claim 5, wherein applying the gain correction includes distributing the combined gain error, correcting the second measurement based on a first portion of the combined gain error and correcting the third measurement based on a second portion of the combined gain error.

7. The system of claim 6, wherein the first portion and the second portion are selected to reduce or minimize current ripple and torque errors.

8. The system of claim 1, wherein the error detection module is configured to correct an offset error of the plurality of reference currents, based on applying a low pass filter to the plurality of reference currents.

9. A method of evaluating current sensor measurements, comprising:
measuring, by a current sensor, three-phase alternating current (AC) signals applied to a three-phase electrical device, the measured AC signals including a first measurement of a first phase current, a second measurement of a second phase current and a third measurement of a third phase current;
applying a transform to the measured AC signals to generate a plurality of reference currents, each reference current of the plurality of reference currents represented as a current vector rotating in a two-dimensional reference frame;
calculating a current angle between the plurality of reference currents;
correlating the current angle to a second order harmonic function; and
determining a gain error associated with the measured AC signals based on the correlating.

10. The method of claim 9, wherein the second order harmonic function is a second order rotating complex vector having a real part and an imaginary part.

11. The method of claim 10, wherein determining the gain error includes estimating a first gain error associated with the first measurement based on the real part, and determining a combined gain error associated with the second measurement and the third measurement based on the imaginary part.

12. The method of claim 11, further comprising applying a gain correction to each of the first measurement, the second measurement and the third measurement.

13. The method of claim 12, wherein applying the gain correction includes distributing the combined gain error, correcting the second measurement based on a first portion of the combined gain error and correcting the third measurement based on a second portion of the combined gain error.

14. The method of claim 13, the first portion and the second portion are selected to reduce or minimize current ripple and torque errors.

15. The method of claim 9, further comprising correcting an offset error of the reference currents, based on applying a low pass filter to the reference currents.

16. A vehicle system comprising:
a memory having computer readable instructions; and
a processing device for executing the computer readable instructions, the computer readable instructions controlling the processing device to perform a method including:
receiving, from a current sensor, measurements of three-phase alternating current (AC) signals applied to a three-phase electrical device, the measurements including a first measurement of a first phase current, a second measurement of a second phase current and a third measurement of a third phase current;
applying a transform to the measurements to generate a plurality of reference currents, each reference current if the plurality of reference currents represented as a current vector rotating in a two-dimensional reference frame;
calculating a current angle between the plurality of reference currents;
correlating the current angle to a second order harmonic function; and
determining a gain error associated with the measurements based on the correlating.

17. The vehicle system of claim 16, wherein the second order harmonic function is a second order rotating complex vector having a real part and an imaginary part.

18. The vehicle system of claim 17, wherein determining the gain error includes estimating a first gain error associated with the first measurement based on the real part, and determining a combined gain error associated with the second measurement and the third measurement based on the imaginary part.

19. The vehicle system of claim 18, further comprising applying a gain correction to each of the first measurement, the second measurement and the third measurement, wherein applying the gain correction includes distributing the combined gain error, correcting the second measurement based on a first portion of the combined gain error and correcting the third measurement based on a second portion of the combined gain error.

20. The vehicle system of claim 16, further comprising correcting an offset error of the plurality of reference currents, based on applying a low pass filter to the plurality of reference currents.
